(19) United States
(12) Patent Application Publication
(10) Pub. No.: US 2009/0079072 A1
(43) Pub. Date: Mar. 26, 2009

(54) Semiconductor device having low dielectric insulating film and manufacturing method of the same

(75) Inventors: Aiko Mizusawa, Kunitachi-shi (JP); Osamu Okada, Hamura-shi (JP); Takeshi Wakabayashi, Sayama-shi (JP); Ichiro Mihara, Tachikawa-shi (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: Casio Computer Co., Ltd., Tokyo (JP)

(21) Appl. No.: 12/001,878

(22) Filed: Dec. 13, 2007

(30) Foreign Application Priority Data
Sep. 21, 2007 (JP) 2007-244977

(51) Int. Cl. H01L 23/488; H01L 21/58

(52) U.S. Cl. 257/738; 438/114; 257/E23.023; 257/E21.575

(57) ABSTRACT

A semiconductor device includes a semiconductor substrate having an integrated circuit. A low dielectric film wiring line laminated structure portion is provided on the semiconductor substrate except a peripheral portion thereof, and is constituted by low dielectric films and wiring lines. The low dielectric film has a relative dielectric constant of 3.0 or lower and a glass transition temperature of 400° C. or higher. An insulating film is formed on the laminated structure portion. A connection pad portion is arranged on the insulating film and connected to a connection pad portion of an uppermost wiring line of the laminated structure portion. A bump electrode is provided on the connection pad portion. A sealing film is provided on the insulating film which surrounds the pump electrode and on the peripheral portion of the semiconductor substrate. The side surfaces of the laminated structure portion are covered with the insulating film or the sealing film.

### CROSS-REFERENCE TO RELATED APPLICATIONS

This application is based upon and claims the benefit of priority from prior Japanese Patent Application No. 2007-244977, filed Sep. 21, 2007, the entire contents of which are incorporated herein by reference.

### BACKGROUND OF THE INVENTION

1. Field of the Invention

The present invention relates to a semiconductor device and a manufacturing method of the device.

2. Description of the Related Art

As conductor devices to be mounted on small-sized electronic devices represented by portable electronic devices and the like, there are known chip size packages (CSPs) each having dimensions substantially equal to that of a semiconductor substrate. Among the CSPs, a CSP in which packaging is completed in a wafer state and which is separated into individual semiconductor devices by dicing is also referred to as a wafer level package (WLP). In Jpn. Pat. Appln. KOKAI Publication No. 2004-349461, a typical structure of the WLP is disclosed. In the semiconductor device described in this prior literature, wiring lines are extended from connection pads on the upper surface of an insulating film which covers the connection pads formed on the semiconductor substrate except their central parts, columnar electrodes are arranged on the upper surfaces of connection pad portions formed on ends of the extended wiring lines, and a sealing film is formed so as to cover the wiring lines between the columnar electrodes on the upper surface of the insulating film. The sealing film is formed so that the upper surface of the sealing film and the upper surfaces of the columnar electrodes are on one plane. Solder balls are provided on the upper surfaces of the columnar electrodes.

Among such semiconductor devices as described above, there is a device in which interlayer insulating film wiring line laminated structure portions each including a laminated structure of interlayer insulating films and the wiring lines are provided between the semiconductor substrate and the insulating film. In this device, when an interval between the wiring lines of the interlayer insulating film wiring line laminated structure portion decreases with miniaturization of the semiconductor devices, a capacity between the wiring lines increases, with the result that a delay of a signal which transmits through the wiring lines increases.

To improve this point, as a material of the interlayer insulating film, much attention is paid to a low dielectric film such as a low-k material having a dielectric constant lower than a dielectric constant of 4.2 to 4.0 of silicon oxide which is generally used as the material of the interlayer insulating film. Examples of the low-k material include SiOC obtained by doping silicon oxide (SiO₂) with carbon (C), and SiOCH further containing H. To further lower the dielectric constant, air-containing porous type low dielectric films are also being investigated.

However, in the above semiconductor device including the low dielectric film, especially the low dielectric film represented by the porous type low dielectric film having a hollow structure has a small mechanical strength and is easily influenced by moisture. As a result, there is a problem that the low dielectric film easily peels from an underlayer.

### BRIEF SUMMARY OF THE INVENTION

An object of the present invention is to provide a semiconductor device capable of remarkably improving a problem of peeling of a low dielectric film, and a manufacturing method of the semiconductor device.

A semiconductor device according to one aspect of the present invention comprises:

a semiconductor substrate, on one surface of which an integrated circuit is formed;

a low dielectric film wiring line laminated structure portion which is provided in a region on the semiconductor substrate except a peripheral portion thereof, and which is constituted of a laminated structure including a plurality of low dielectric films and a plurality of wiring lines, each of the low dielectric films having a relative dielectric constant of 3.0 or lower and a glass transition temperature of 400° C. or higher;

an insulating film formed on the low dielectric film wiring line laminated structure portion;

a connection pad portion for an electrode, arranged on the insulating film to be connected to a connection pad portion of an uppermost wiring line of the low dielectric film wiring line laminated structure portion;

a bump electrode for external connection, provided on the connection pad portion for the electrode; and

a sealing film provided on a part of the insulating film which surrounds the pump electrode for the external connection and on the peripheral portion of the semiconductor substrate,

wherein side surfaces of the low dielectric film wiring line laminated structure portion are covered with one of the insulating film and the sealing film.

Moreover, a manufacturing method of a semiconductor device according to another aspect of the present invention comprises:

preparing a semiconductor wafer, on one surface of which an integrated circuit is formed, which includes a low dielectric film wiring line laminated structure portion constituted by low dielectric films and wiring lines, the low dielectric films having a relative dielectric constant of 3.0 or lower and a glass transition temperature of 400° C. or higher, and which includes an insulating film formed on the low dielectric film wiring line laminated structure portion and made of an organic resin;

removing parts of the insulating film and the low dielectric film wiring line laminated structure portion in regions above dicing streets and regions on opposite sides of the dicing streets by applying laser beams, and forming a groove exposing side surfaces of the low dielectric film wiring line laminated structure portion and the side surfaces of the insulating film;

forming a connection pad portion for an electrode on the insulating film to be connected to a connecting pad portion of an uppermost wiring line of the low dielectric film wiring line laminated structure portion;

forming a bump electrode for external connection on the connection pad portion for the electrode;

forming a sealing film which covers a part of an upper surface of the insulating film surrounding the bump electrode for external connection, the side surfaces of the low dielectric film wiring line laminated structure portion, and the side surfaces of the insulating film; and

cutting the sealing film and the semiconductor wafer along the dicing streets, thereby obtaining a plurality of semiconductor devices.

According to the present invention, the region on the semiconductor substrate except its peripheral portion is provided with the low dielectric film wiring line laminated structure portion including the laminated structure of the low dielectric films and the wiring lines, and the side surfaces of this low dielectric film wiring line laminated structure portion are covered with the sealing film (or the insulating film). In consequence, the peeling of the low dielectric films can be prevented.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a sectional view of a semiconductor device as a first embodiment of the present invention;

FIG. 2 is a sectional view of an assembly first prepared during manufacturing of the semiconductor device shown in FIG. 1;

FIG. 3 is a sectional view of an assembly in a step subsequent to FIG. 2;

FIG. 4 is a sectional view of an assembly in a step subsequent to FIG. 3;

FIG. 5 is a sectional view of an assembly in a step subsequent to FIG. 4;

FIG. 6 is a sectional view of an assembly in a step subsequent to FIG. 5;

FIG. 7 is a sectional view of an assembly in a step subsequent to FIG. 6;

FIG. 8 is a sectional view of an assembly in a step subsequent to FIG. 7;

FIG. 9 is a sectional view of an assembly in a step subsequent to FIG. 8;

FIG. 10 is a sectional view of an assembly in a step subsequent to FIG. 9;

FIG. 11 is a sectional view of an assembly in a step subsequent to FIG. 10;

FIG. 12 is a sectional view of a semiconductor device as a second embodiment of the present invention;

FIG. 13 is a sectional view of an assembly in a predetermined step during manufacturing of the semiconductor device shown in FIG. 12;

FIG. 14 is a sectional view of an assembly in a step subsequent to FIG. 13;

FIG. 15 is a sectional view of an assembly in a step subsequent to FIG. 14;

FIG. 16 is a sectional view of a semiconductor device as a third embodiment of the present invention;

FIG. 17 is a sectional view of a semiconductor device according to a fourth embodiment of the present invention;

FIG. 18 is a sectional view of a semiconductor device according to a fifth embodiment of the present invention; and

FIG. 19 is a sectional view of a semiconductor device according to a sixth embodiment of the present invention.

### DETAILED DESCRIPTION OF THE INVENTION

### First Embodiment

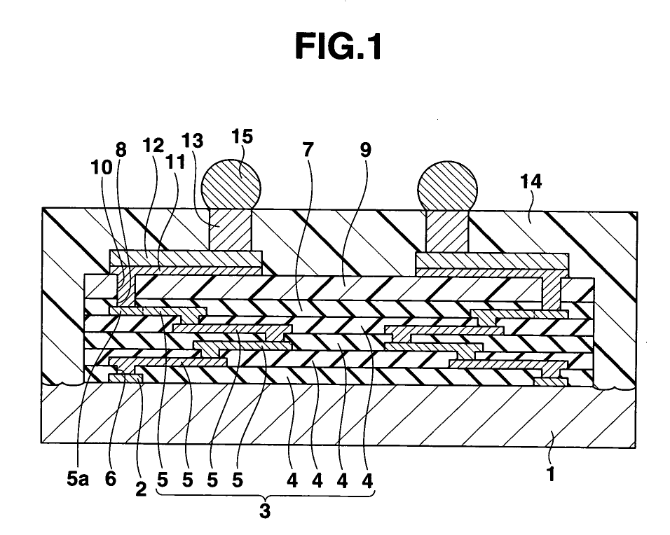

FIG. 1 shows a sectional view of a semiconductor device as a first embodiment of the present invention. This semiconductor device includes a silicon substrate (a semiconductor substrate) 1. On the upper surface of the silicon substrate 1, an integrated circuit having a predetermined function is provided, and in a peripheral portion of the upper surface, a plurality of or large number of connection pads 2 made of an aluminum-based metal or the like are electrically connected to the integrated circuit, although the figure shows only two pads.

On the upper surfaces of the silicon substrate 1 and the connection pads 2, low dielectric film/wiring line/laminated structure portions 3 are provided. The laminated structure portion 3 has a structure in which there are alternately laminated a plurality of layers, for example, four layers of low dielectric films 4 and the same number of layers of wiring lines 5 made of an aluminum-based metal or the like. Examples of a material of the low dielectric films 4 include a polysiloxane-based material having an Si—O bond and an Si—H bond (HSQ:Hydrogen silsesquioxane having a relative dielectric constant of 3.0), a polysiloxane-based material having an Si—O bond and an Si—CH₃ bond (MSQ:Methyl silsesquioxane having a relative dielectric constant of 2.7-2.9), a carbon-doped silicon oxide (SiOC having a relative dielectric constant of 2.7-2.9) and an organic polymer-based low-k material. The materials having a relative dielectric constant of 3.0 or lower and a glass transition temperature of 400° C. or higher can be used.

Examples of the organic polymer-based low-k material include “SILK (having a relative dielectric constant of 2.6)” produced by Dow Chemical Company and “FLARE (having a relative dielectric constant of 2.8)” produced by Honeywell Electronic Materials. The glass transition temperature of 400° C. or higher is a condition for tolerance to a temperature in a manufacturing step or steps to be described later. A porous type of each of the above materials may also be used.

Besides the above, the material of the low dielectric films 4 may also be a material which has a relative dielectric constant higher than 3.0 in a normal condition, but can have a relative dielectric constant of 3.0 or lower and a glass transition temperature of 400° C. or higher when it becomes porous. For example, fluorinated silicate glass (FSG having a relative dielectric constant of 3.5-3.7), boron-doped silicate glass (BSG having a relative dielectric constant of 3.5) or silicon oxide (having a relative dielectric constant of 4.0-4.2) may be used.

In the low dielectric film wiring line laminated structure portion 3, the wiring lines 5 in the respective layers are electrically connected to each other. One end portion of the wiring line 5 of the lowermost layer is electrically connected to the connection pad 2 via an opening 6 provided in the low dielectric film 4 of the lowermost layer. Connection pad portions 5a of the wiring lines 5 of an uppermost layer are arranged on upper surface peripheral portion of the low dielectric film 4 of the uppermost layer.

A passivation film 7 made of an inorganic material such as silicon oxide or a low dielectric material is provided on the upper surfaces of the uppermost wiring lines 5 and the low dielectric films 4 of the uppermost layer. Openings 8 are formed through the passivation film 7 in portions corresponding to the connection pad portions 5a of the wiring lines 5 of the uppermost layer. On the upper surface of the passivation film 7, there is provided a protective film 9 made of an organic material containing polyimide, epoxy, phenol, bismaleimide, acryl, synthetic rubber, polybenzoxide or the like as a main component. Openings 10 are formed through the protective film 9 in portions corresponding to the openings 8 of the passivation film 7.

On the upper surface of the protective film 9, metallic underlayers 11 made of copper or the like are provided. On the whole upper surface of each of the metallic underlayers 11, an upper layer wiring line 12 made of copper is provided. End portions of the metallic underlayers 11 are electrically connected to the connection pad portions 5a of the wiring lines 5 of the uppermost layer via the openings 8, 10 of the passivation film 7 and the protective film 9. On the upper surfaces of connection pad portions of the upper layer wiring lines 12, there are provided bump electrodes or columnar electrodes 13 for external connection made of copper.

On the upper surfaces of the upper layer wiring lines 12 and the protective film 9, and the upper surface of the peripheral portion of the silicon substrate 1, there is provided a sealing film or layer 14 made of an organic material such as an epoxy-based resin so that the upper surface of the sealing film and the upper surfaces of the columnar electrodes 13 are on one plane. In this state, the side surfaces of the low dielectric film wiring line laminated structure portion 3, the passivation film 7 and the protective film 9 are entirely covered with a portion of the sealing film 14 on the upper surface of the silicon substrate 1. Solder balls 15 are provided on the upper surfaces of the columnar electrodes 13.

As described above, in this semiconductor device, a region on the silicon substrate 1 except the peripheral portion is provided with the low dielectric film wiring line laminated structure portion 3 each including the laminated structure of the low dielectric films 4 and the wiring lines 5, and the side surfaces of the low dielectric film wiring line laminated structure portion 3, the passivation film 7 and the protective film 9 are covered with the sealing film 14. Therefore, the low dielectric film wiring line laminated structure portion 3 does not easily peel from the silicon substrate 1.

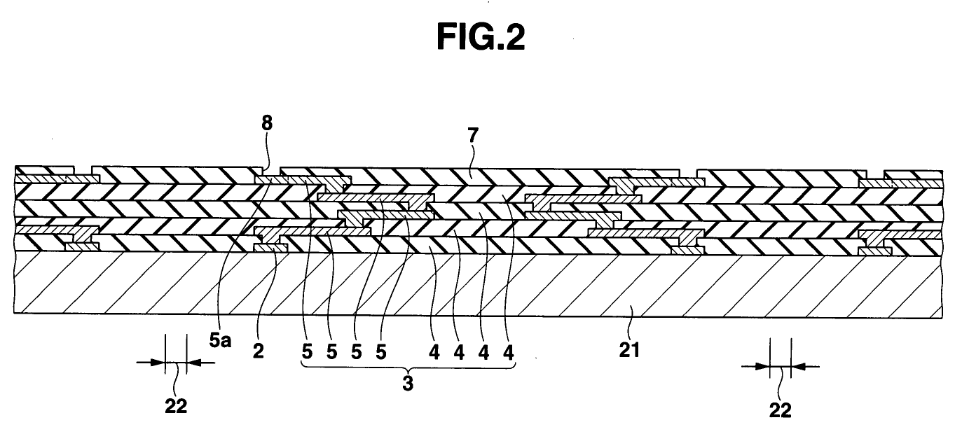

Next, one example of a manufacturing method of the semiconductor device having an aforementioned construction will be described. First, as shown in FIG. 2, an assembly is prepared in which on a silicon substrate (hereinafter referred to as a semiconductor wafer 21) having a wafer state, there are arranged the connection pads 2 and the low dielectric film wiring line laminated structure portions 3 each including four layers of low dielectric films 4 and wiring lines 5, respectively. In the assembly, the passivation film 7 is provided on the laminated structure portions 3, and the centers of the connection pad portions 5a of the wiring lines 5 of the uppermost layer are exposed via the openings 8 provided in the passivation film 7.

Examples of a low dielectric film material 4 may be those, including a porous type, as described above, which have a relative dielectric constant of 3.0 or lower and a glass transition temperature of 400° C. or higher. It is to be noted that regions denoted with reference numeral 22 in FIG. 2 are regions corresponding to dicing streets.

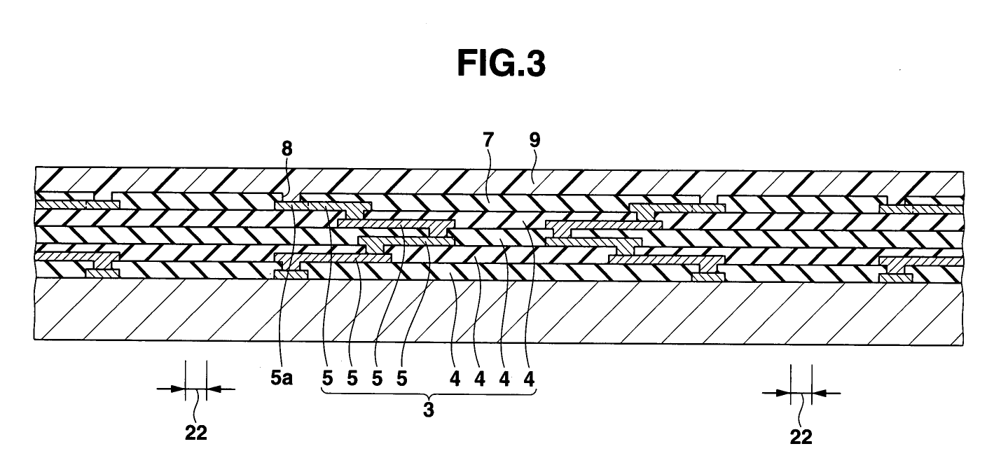

Next, as shown in FIG. 3, by a screen printing process, a spin coating process or the like, the protective film 9 made of an organic material such as a polyimide-based resin is formed on the upper surface of the passivation film 7 and the upper surfaces of the connection pad portions 5a of the wiring lines 5 of the uppermost layer exposed via the openings 8 of the passivation film 7.

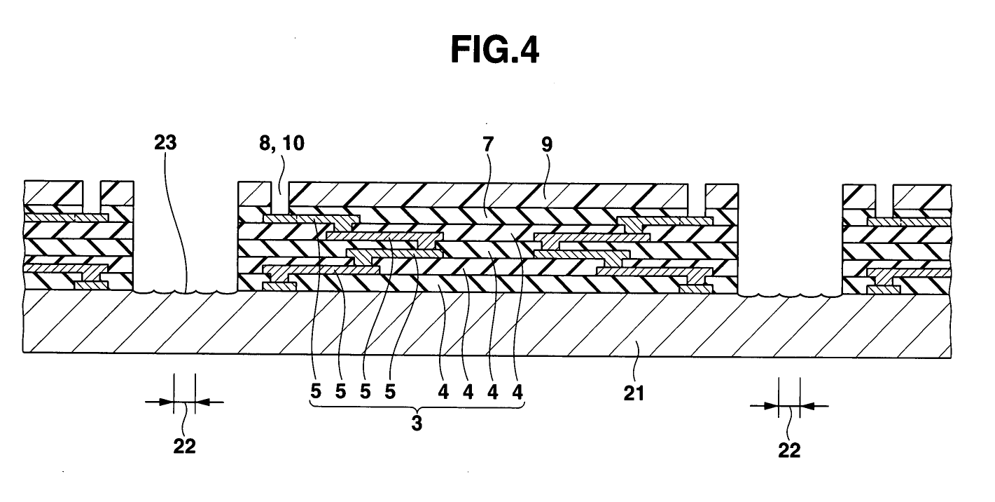

Next, as shown in FIG. 4, by laser processing which emits a laser beam, there are removed portions of the protective film 9, the passivation film 7 and four layers of the low dielectric films 4 positioned in regions of the dicing streets 22 and regions on opposite sides of the streets to form latticed grooves 23. Thus, the upper surface of the silicon substrate 1 is exposed in a lattice form through the grooves. The openings 8 are made in portions of the passivation film 7 on the connection pad portions 5a, and the openings 10 are made in portions of the protective film 9 on these openings. The low dielectric films 4 are brittle. Therefore, if the grooves 23 are cut in the films 4 by using a blade, the cut surface of the low dielectric films 4 will have many notches and cracks. In view of this, it is recommended that the laser beam be applied to the cut surface to make grooves 23. When irradiated with the laser beam, the upper surface of the silicon substrate 1 melts, and molten silicon particles jump and then fall onto the silicon substrate 1. Inevitably, each groove 23 will have an uneven bottom surface as shown in FIG. 4. The application of the laser beam may be terminated when the grooves 23 reach the field oxide film (not shown) that is formed, as in most cases, on the silicon substrate 1.

In this state, the upper surface of the semiconductor wafer 21 in the regions of the dicing streets 22 and the regions on opposite sides of the streets is exposed via the grooves 23 as described above. Moreover, portions of the four layers of the low dielectric films 4, the passivation film 7 and the protective film 9 laminated on the semiconductor wafer 21 are separated from one another by the grooves 23. In consequence, a plurality of low dielectric film wiring line laminated structure portions 3 independent of one another are formed on the wafer 21.

As one example, a width of the groove 23 is 10 to 1000 μm×2 plus a width of the dicing street (a dicing cutter) 22. As a result, in the completed device shown in FIG. 1, a width of the portion of the sealing film 14 which covers the side surfaces of the low dielectric film wiring line laminated structure portion 3, the passivation film 7 and the protective film 9 is 10 to 1000 μm.

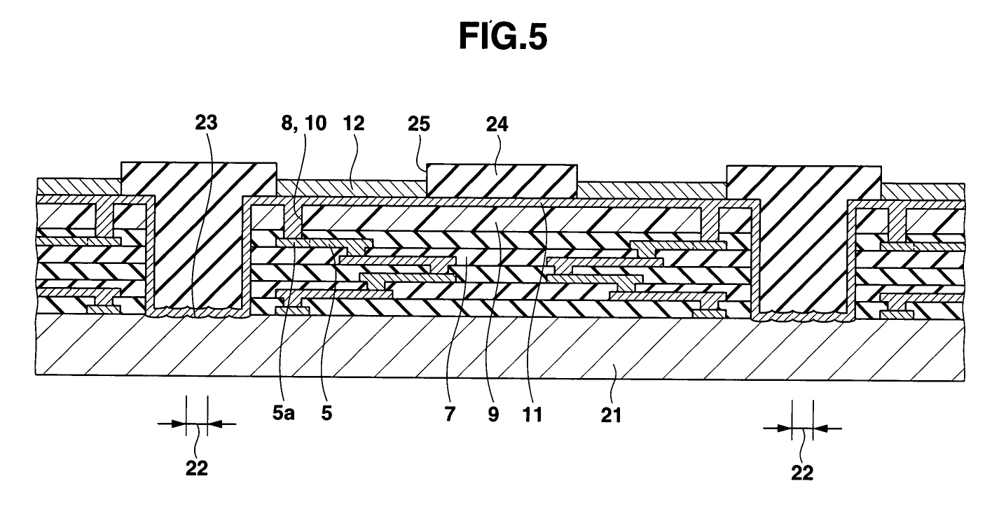

Next, as shown in FIG. 5, the metallic underlayers 11 are formed on the upper surfaces of the connection pad portions 5a of the wiring lines 5 of the uppermost layer exposed via the openings 8, 10 of the passivation film 7 and the protective film 9, on the portions of the upper surface of the semiconductor wafer 21 exposed via the grooves 23, and on the whole upper surface of the protective film 9. In this case, the metallic underlayers 11 may be formed by an only copper layer formed by electroless plating, an only copper layer formed by sputtering, or a copper layer formed by the sputtering on a thin film layer of titanium or the like formed by the sputtering.

Next, plating resist films 24 are formed on the upper surfaces of the metallic underlayers 11, and followed by patterning. As a result, openings 25 are formed in portions of the plating resist films 24 corresponding to regions in which the upper layer wiring lines 12 are formed. Next, electrolytic plating of copper is performed by use of the metallic underlayers 11 as plating current paths to thereby form the upper layer wiring lines 12 on the upper surfaces of the metallic underlayers 11 in the openings 25 of the plating resist films 24. Next, the plating resist films 24 are peeled.

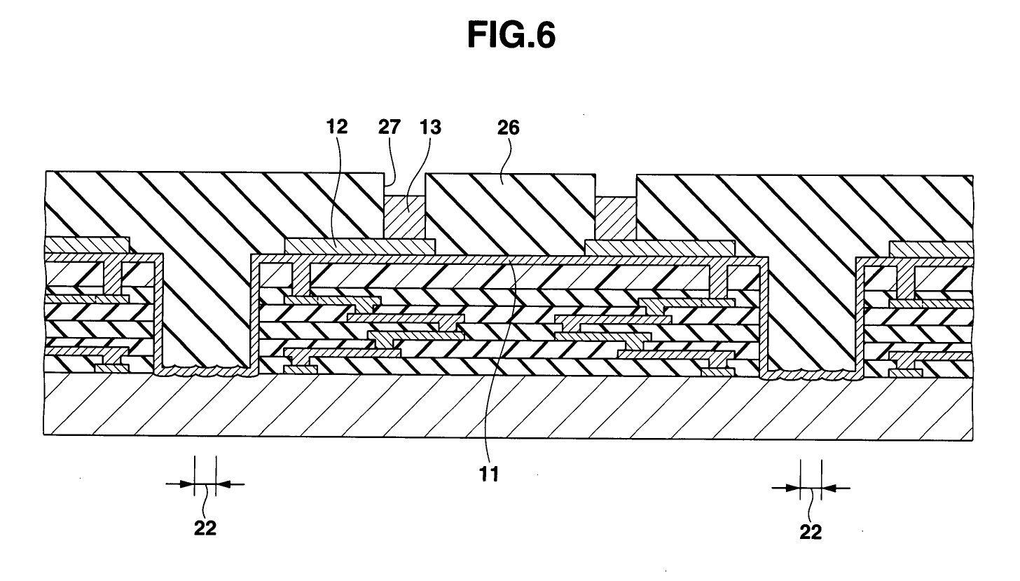

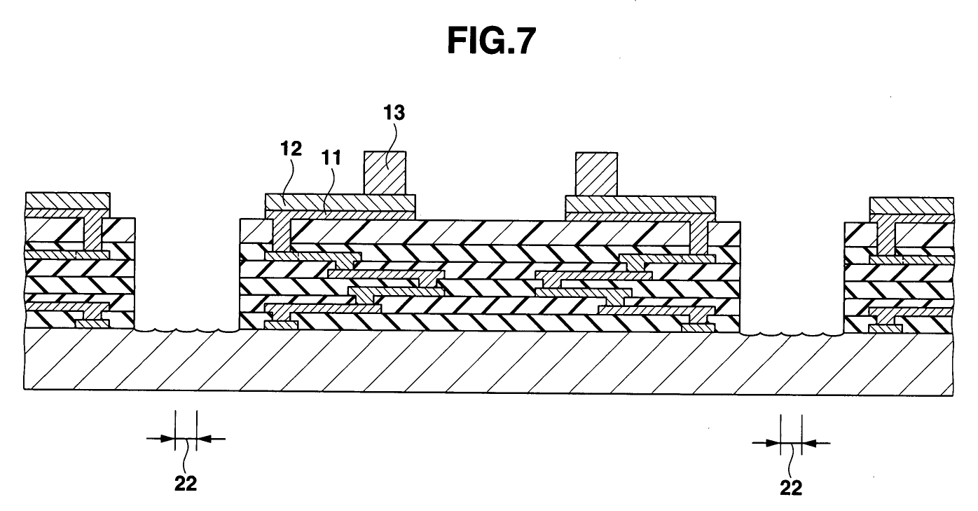

Next, as shown in FIG. 6, on the upper surfaces of the metallic underlayers 11 and the upper layer wiring lines 12, a plating resist film 26 is formed by depositing and then patterning. Thus, this case, openings 27 are formed in the plating resist film 26 in portions corresponding to the connection pad portions (regions where the columnar electrodes 13 are formed) of the upper layer wiring lines 12. Next, the electrolytic plating of copper is performed by use of the metallic underlayers 11 as the plating current paths, whereby the columnar electrodes 13 each having a height of 50 to 150 μm are formed on the upper surfaces of the connection pad portions of the upper layer wiring lines 12 in the openings 27 of the plating resist film 26. Next, the plating resist film 26 is entirely peeled or removed. Then, unnecessary portions of the metallic underlayers 11 are etched and removed by use of the upper layer wiring lines 12 as masks. Consequently, as shown in FIG. 7, the metallic underlayers 11 only under the upper layer wiring lines 12 are left.

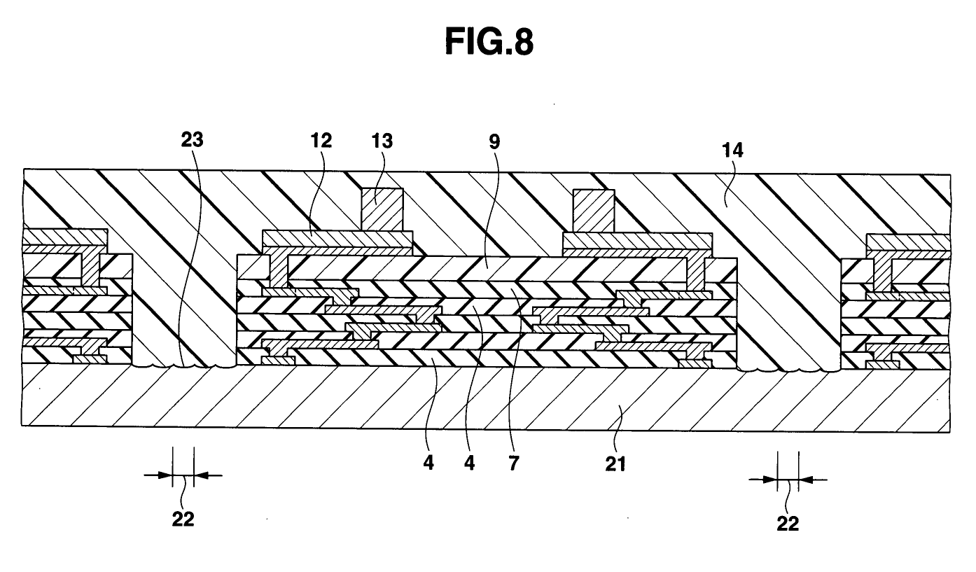

Next, as shown in FIG. 8, by a screen printing process, a spin coating process or the like, the sealing film 14 made of an organic material such as an epoxy-based resin is entirely formed on the upper surfaces of the upper layer wiring lines 12, the columnar electrodes 13 and the protective film 9, as well as on the upper surface of the semiconductor wafer 21 exposed via the grooves 23 so that a thickness of the sealing film 14 is larger than a height of the columnar electrodes 13. Therefore, in this state, the upper surfaces of the columnar electrodes 13 are covered with an upper part of the sealing film 14. The side surfaces of the protective film 9, the passivation film 7 and four layers of the low dielectric films 4 are also entirely covered with the sealing film 14.

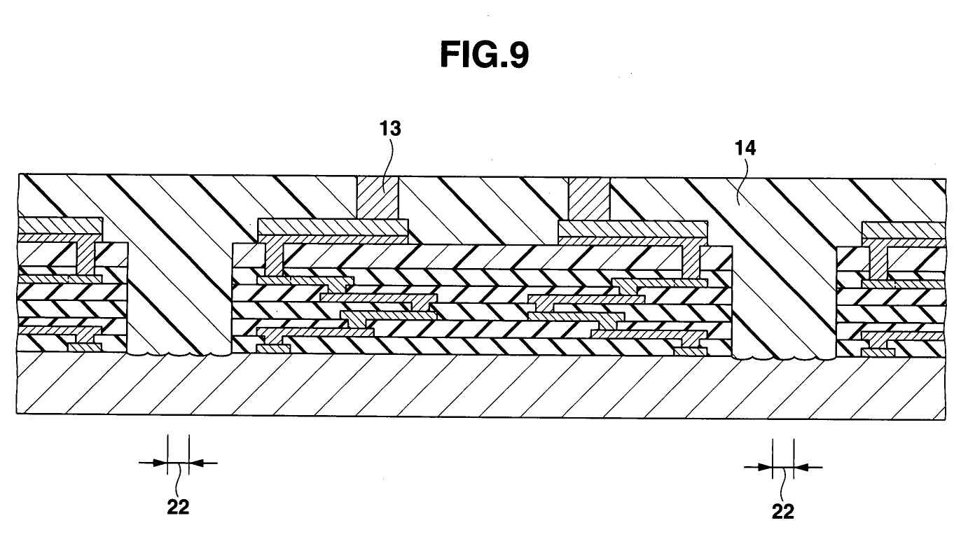

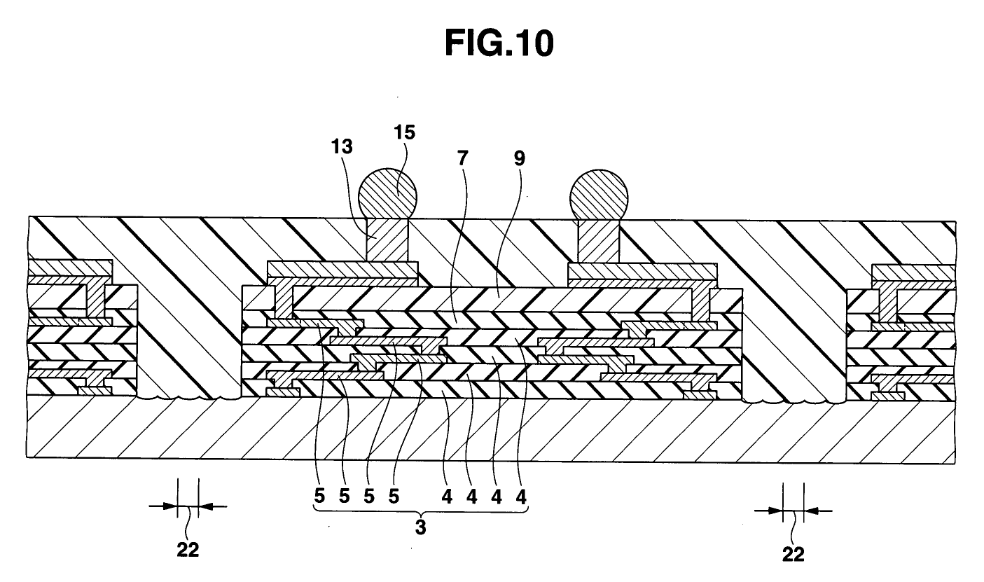

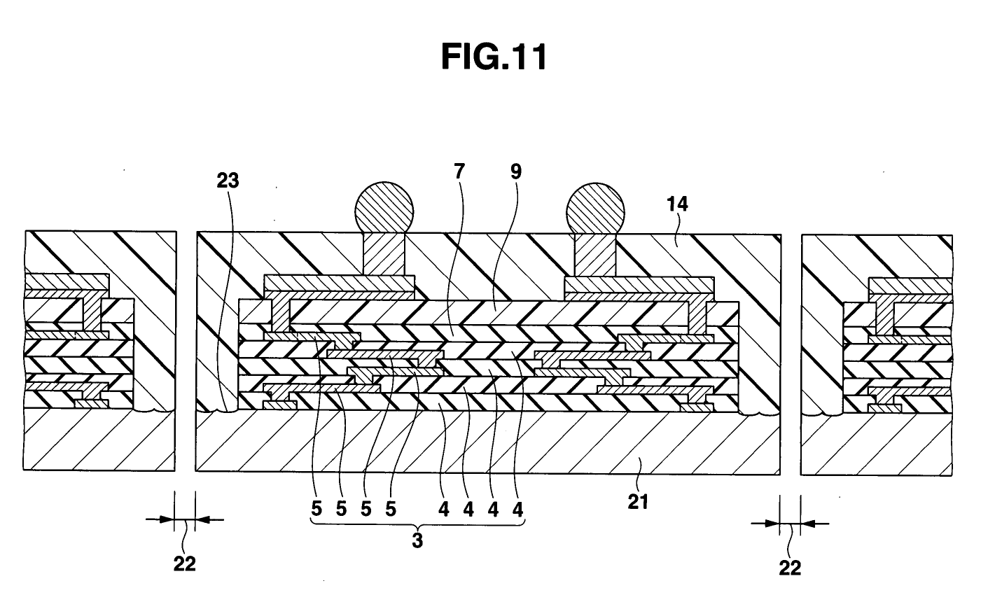

Next, a portion of the upper surface of the sealing film 14 is appropriately ground to expose the upper surfaces of the columnar electrodes 13 as shown in FIG. 9. Moreover, the exposed upper surfaces of the columnar electrodes 13 and the upper surface of the sealing film 14 are flattened so that these upper surfaces are on one plane. In flattening this upper surface of the sealing film 14, upper surface portions of the columnar electrodes 13 may be ground together with the upper portion of the sealing film 14 as much as several to ten or more micrometers. Next, as shown in FIG. 10, the solder balls 15 are formed on the upper surfaces of the columnar electrodes 13. Next, as shown in FIG. 11, the sealing film 14 and the semiconductor wafer 21 are cut along the dicing streets 22 in the centers of the grooves 23. As described above, since the grooves 23 have been formed to be wider than the dicing streets 22, there are obtained a plurality of semiconductor devices each having a structure in which, as shown in FIG. 1, the side surfaces of the low dielectric film wiring line laminated structure portion 3 are covered with the sealing film 14, and further the side surfaces of the passivation film 7 and the upper surface and the side surfaces of the protective film 9 are also covered with the sealing film 14.

In the above embodiment, the exposed part of the upper surface of the semiconductor wafer 21 is shown like a bottom portion of the groove 23, but the upper surface of the semiconductor wafer 21 may be partially removed by a laser beam to form the groove 23, so that the bottom portion of the groove 23 may be below the upper surface of the semiconductor wafer 21. If an insulating film such as a field oxide film is formed on the upper surface of the semiconductor wafer 21, the upper surface of this field oxide film or an intermediate portion of a film thickness thereof may be the bottom portion of the groove 23, and the bottom portion of the groove 23 may be positioned above the upper surface of the semiconductor wafer 21.

### Second Embodiment

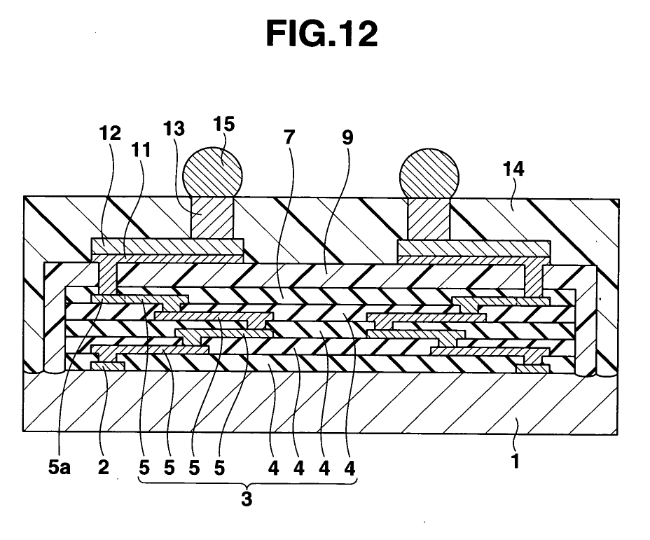

FIG. 12 shows a sectional view of a semiconductor device as a second embodiment of the present invention. This semiconductor device is different from the semiconductor device shown in FIG. 1 in that the upper surface and the side surfaces of the passivation film 7 and the side surfaces of the low dielectric film wiring line laminated structure portion 3 are covered with the protective film 9, and the side surfaces of the protective film 9 is covered with the sealing film 14.

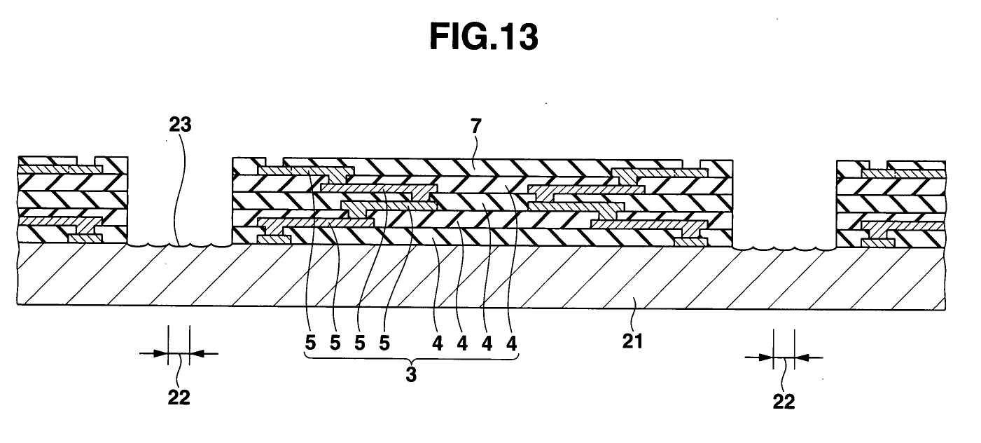

As one example of manufacturing this semiconductor device, an assembly shown in FIG. 3 is prepared, and then, as shown in FIG. 13, by laser processing which emits a laser beam, the grooves 23 are formed in the passivation film 7 and four layers of the low dielectric films 4 in regions of the dicing streets 22 and regions on opposite sides of the streets.

In this state, the upper surfaces of a semiconductor wafer 21 in the dicing streets 22 and the regions on opposite sides of the streets are exposed via the grooves 23. Moreover, units which are laminated on the semiconductor wafer 21 and which are each constituted of four layers of the low dielectric films 4 and the passivation film 7 are separated from one another along the grooves 23. In consequence, a plurality of low dielectric film wiring line laminated structure portions 3 shown in FIG. 13 are formed on the semiconductor wafer 21.

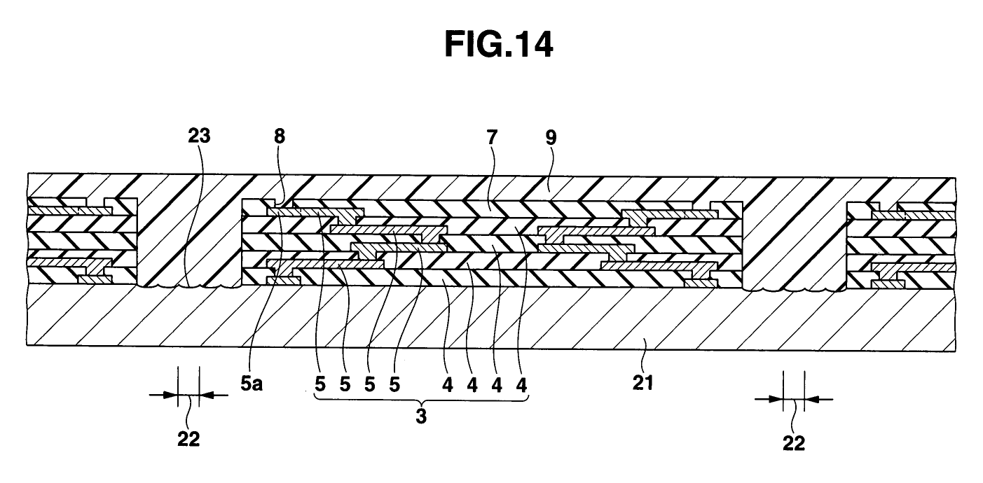

Next, as shown in FIG. 14, by a screen printing process, a spin coating process or the like, the protective film 9 made of an organic material such as a polyimide-based resin is formed on the upper surfaces of the connection pad portions Sa of the wiring lines 5 of the uppermost layer exposed via the openings 8 of the passivation film 7, on the upper surface of the passivation film 7, and on the upper surfaces of portions of the semiconductor wafer 21 exposed via the grooves 23.

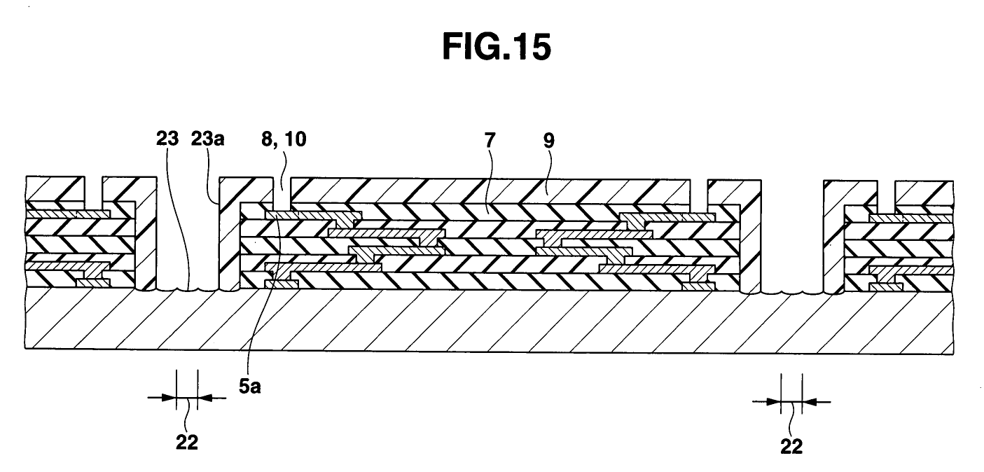

Next, as shown in FIG. 15, by laser processing which emits a laser beam or cut processing using a dicing blade, grooves 23a slightly narrower than the aforementioned grooves 23 are formed in the protective film 9 in the regions of the dicing streets 22 and the regions on opposite sides of the streets, and openings 10 are formed in portions of the protective film 9 corresponding to the openings 8 of the passivation film 7. Since the subsequent steps are similar to the steps of FIG. 5 et seq. of the first embodiment, description thereof is omitted.

### Third Embodiment

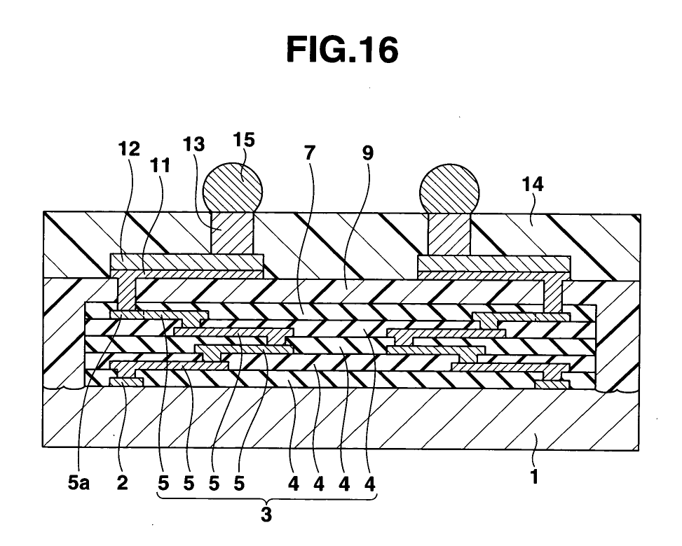

FIG. 16 shows a sectional view of a semiconductor device as a third embodiment of the present invention. The third embodiment is different from the second embodiment in that the protective film 9 which covers the upper surface and the side surfaces of the passivation film 7 and the side surfaces of the low dielectric films 4 is extended to the same plane as that of the side surface of the silicon substrate 1.

To produce the above semiconductor device, the groove 23 is completely filled with a part of the protective film 9, as shown in FIG. 14, so that the groove 23a as shown in FIG. 15 may not be formed. In this case, therefore, the sealing film 14, the protective film 9 and the semiconductor wafer 21 are cut along the dicing streets 22 in the last step.

### Fourth Embodiment

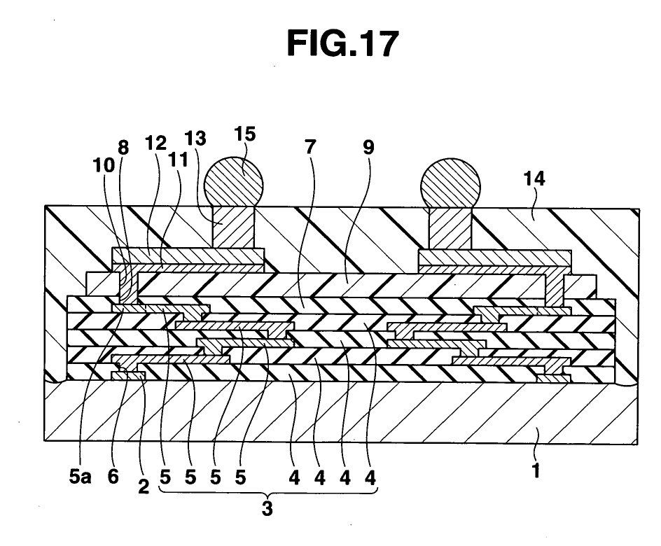

FIG. 17 is a sectional view of a semiconductor device according to a fourth embodiment of this invention. This semiconductor device is different from the semiconductor device shown in FIG. 1 in that the outer side surfaces of the protective film 9 are located inward from the outer side surfaces of the low dielectric film wiring line laminated structure portion 3 and the passivation film 7. In other words, the protective film 9 is formed on the passivation film 7 and smaller than the passivation film 7. In this case, the outer side surfaces of the passivation film 7 and the low dielectric film wiring line laminated structure portion 3 substantially form one plane.

To manufacture this semiconductor device, the protective film 9 is formed on the entire surface of the passivation film 7, as shown in FIG. 3. Then, the protective film 9 is patterned by means of photolithography. Thereafter, laser beams are applied to the passivation film 7 and the low dielectric film wiring line laminated structure portion 3, making grooves 23.

In the above method for manufacturing the semiconductor device, the passivation film 7 and the low dielectric film wiring line laminated structure portion 3 are processed with the laser beams, and the protective film 9 is not. This method is particularly effective in the case where the protective film 9 is made of a material, such as a polyimide-based resin, which easily absorbs laser energy and cannot be easily cut by radiation of laser beams.

### Fifth Embodiment

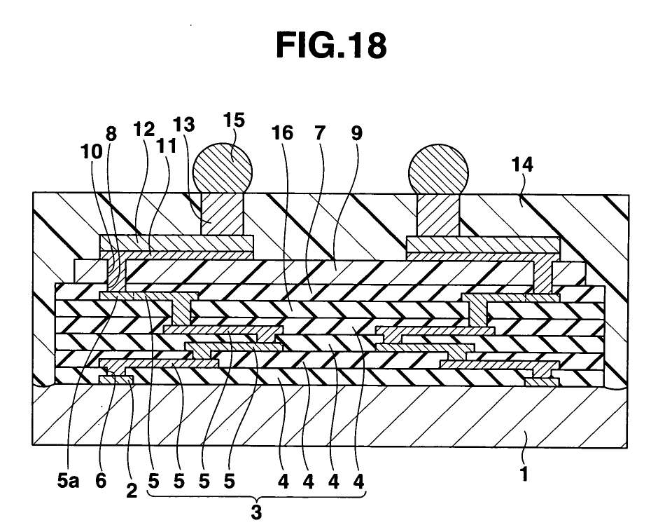

FIG. 18 is a sectional view of a semiconductor device according to a fifth embodiment of the present invention. This semiconductor device is different from the semiconductor device shown in FIG. 17 in that the low dielectric film wiring line laminated structure portion 3 has a lower passivation film 16 between the uppermost wiring line 5 and the uppermost low dielectric film 4.

In this case, the upper passivation film 7 and the lower passivation film 16 may be formed of the same inorganic material, such as silicon oxide. Alternatively, one passivation film, for example the upper film 7 may be formed of silicon nitride, while the other passivation film, for example the lower film 16 may be formed of silicon oxide.

### Sixth Embodiment

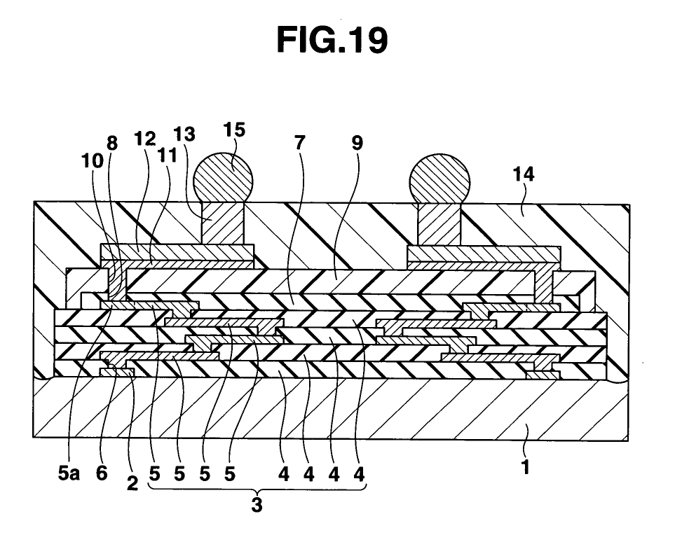

FIG. 19 is a sectional view of a semiconductor device according to a sixth embodiment of the present invention. This semiconductor device is different from the semiconductor device shown in FIG. 17 in that the outer side surfaces of the passivation film 7 are located inward from those of the protective film 9. In other words, the passivation film 7 is formed on the low dielectric film wiring line laminated structure portion 3 and smaller than the protective film 9. The side portions of the protective film 9 are downwardly projected to cover the outer side surface of the passivation film 7.

To manufacture this semiconductor device, the passivation film 7 is formed on the overall surface of the low dielectric film wiring line laminated structure portion 3. Then, the passivation film 7 is patterned by means of photolithography. Thereafter, the protective film 9 is formed on the passivation film 7 and parts of the low dielectric film wiring line laminated structure portion 3 which are not covered by the passivation film 7. Thereafter, the protective film 9 is patterned by means of photolithography. Then, the laminated structure portion 3 is processed by radiation of laser beams, thereby forming grooves 23.

In the above method for manufacturing the semiconductor device, only the low dielectric film wiring line laminated structure portion 3 is processed with laser beams, and the passivation film 7 and the protective film 9 are not. Optimal laser-beam process conditions can therefore be set for the processing of the low dielectric film wiring line laminated structure portion 3, particularly the low dielectric film 4. Hence, the low dielectric film 4 can be processed efficiently with high precision. Alternately, it is to be noted that the passivation film 7 may be of the same size as the protective film 9, so that the side surfaces of the passivation film 7 and the side surfaces of the protective film 9 form substantially the same plane.

### Other Embodiments

Referring to FIG. 17, for example, the uppermost low dielectric film 4 of the laminated structure portion 3 may be a lower passivation film. In other words, the laminated structure portion 3 may have a lower passivation film formed between the uppermost wiring line 5 and the second uppermost wiring line 5.

In this case, the passivation film 7 and the lower passivation film may be formed of the same inorganic material, such as silicon oxide. Alternatively, the passivation film 7 may be formed of silicon nitride, while the lower passivation film may be formed of silicon oxide.

In the above embodiments, the upper wiring lines 12 are formed on the protective film 9 and the columnar electrodes 13 are formed on the connection pad portion on the upper wiring lines 12. However, this invention is applicable to a structure in which only the connection pad portion is formed on the protective film 9 and bump electrodes for external connection, such as solder balls 15, are formed on the connection pad portion.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate, on one surface of which an integrated circuit is formed;
a low dielectric film wiring line laminated structure portion which is provided in a region on the semiconductor substrate except a peripheral portion thereof, and which is constituted of a laminated structure including a plurality of low dielectric films and a plurality of wiring lines, each of the low dielectric films having a relative dielectric constant of 3.0 or lower and a glass transition temperature of 400° C. or higher;
an insulating film formed on the low dielectric film wiring line laminated structure portion;
a connection pad portion for an electrode, arranged on the insulating film to be connected to a connection pad portion of an uppermost wiring line of the low dielectric film wiring line laminated structure portion;
a bump electrode for external connection, provided on the connection pad portion for the electrode; and
a sealing film provided on a part of the insulating film which surrounds the pump electrode for the external connection and on the peripheral portion of the semiconductor substrate,
wherein side surfaces of the low dielectric film wiring line laminated structure portion are covered with one of the insulating film and the sealing film.

2. The semiconductor device according to claim 1, wherein the insulating film includes a passivation film formed of an inorganic material and a protective film formed of an organic material.

3. The semiconductor device according to claim 2, wherein side surfaces of the protective film, the passivation film and the low dielectric film wiring line laminated structure portion substantially form one plane, and the side surfaces of the protective film, the insulating film and the low dielectric film wiring line laminated structure portion are covered with the sealing film.

4. The semiconductor device according to claim 2, wherein side surfaces of the passivation film and the low dielectric film wiring line laminated structure portion substantially form one plane, and the side surfaces of the passivation film and the low dielectric film wiring line laminated structure portion are covered with the protective film.

5. The semiconductor device according to claim 4, wherein the side surfaces of the protective film are covered with the sealing film.

6. The semiconductor device according to claim 2, wherein the side surfaces of the protective film are located inward from the side surfaces of the low dielectric film wiring line laminated structure portion.

7. The semiconductor device according to claim 6, wherein the side surfaces of the passivation film and the low dielectric film wiring line laminated structure portion substantially form one plane.

8. The semiconductor device according to claim 6, wherein the side surfaces of the passivation film are located inward from the side surfaces of the protective film.

9. The semiconductor device according to claim 6, wherein the side surfaces of the protective film and the passivation film substantially form one plane.

10. The semiconductor device according to claim 1, wherein the low dielectric film wiring line laminated structure portion has a lower passivation film formed between the uppermost wiring line and a second uppermost wiring line.

11. The semiconductor device according to claim 1, wherein the low dielectric film wiring line laminated structure portion has a lower passivation film formed between the uppermost wiring line and an uppermost low dielectric film.

12. The semiconductor device according to claim 11, wherein the lower passivation film is formed of silicon oxide.

13. The semiconductor device according to claim 12, wherein the insulating film includes a passivation film formed of silicon nitride.

14. The semiconductor device according to claim 1, wherein an upper wiring line having the connection pad portion for the electrode is formed on the insulating film.

15. The semiconductor device according to claim 14, wherein the bump electrode is a columnar electrode.

16. The semiconductor device according to claim 15, wherein a solder ball is provided on the columnar electrode.

17. The semiconductor device according to claim 1, wherein the low dielectric film includes one of a polysiloxane-based material having an Si—O bond and an Si—H bond, a polysiloxane-based material having an Si—O bond and an Si—CH₃ bond, a carbon-doped silicon oxide and an organic polymer-based low-k material, or a porous type of one of a fluorine-doped silicon oxide, boron-doped silicon oxide and silicon oxide.

18. A semiconductor device comprising:
a semiconductor substrate having an integrated circuit on one surface thereof;
a low dielectric film, which is provided in a region on the semiconductor substrate except a peripheral portion thereof and which has a relative dielectric constant of 3.0 or lower and a glass transition temperature of 400° C. or higher;
a wiring line formed on the low dielectric film;
an insulating film formed on the wiring line and having an opening which exposes at least a part of the wiring line;
a conductive layer formed on the insulating film and electrically connected to the wiring line through the opening;
an electrode for external connection electrically connected to the conductive layer; and
a sealing film, which is formed on a part of the insulating film surrounding the electrode for external connection and a peripheral portion of the semiconductor substrate and which supports side surfaces of the low dielectric film.

19. A semiconductor device comprising:
a semiconductor substrate, on one surface of which an integrated circuit is formed;
a low dielectric film wiring line laminated structure portion, which is provided in a region on the semiconductor substrate except a peripheral portion thereof, and constituted of a laminated structure including a low dielectric film and a wiring line, the low dielectric film having a relative dielectric constant of 3.0 or lower and a glass transition temperature of 400° C. or higher;
an insulating film formed on the low dielectric film wiring line laminated structure portion and having an opening which exposes at least a part of the wiring line;
a conductive layer formed on the insulating film and electrically connected to the wiring line through the opening;
an electrode for external connection electrically connected to the conductive layer; and
a sealing film, which is formed on a part of the insulating film surrounding the electrode for external connection and a peripheral portion of the semiconductor substrate and which supports side surfaces of the low dielectric film.

20. A method of manufacturing a semiconductor device, comprising:
preparing a semiconductor wafer, on one surface of which an integrated circuit is formed, which includes a low dielectric film wiring line laminated structure portion constituted by low dielectric films and wiring lines, the low dielectric films having a relative dielectric constant of 3.0 or lower and a glass transition temperature of 400° C. or higher, and which includes an insulating film formed on the low dielectric film wiring line laminated structure portion and made of an organic resin;
removing parts of the insulating film and the low dielectric film wiring line laminated structure portion in regions above dicing streets and regions on opposite sides of the dicing streets by applying laser beams, and forming a groove exposing side surfaces of the low dielectric film wiring line laminated structure portion and the side surfaces of the insulating film;
forming a connection pad portion for an electrode on the insulating film to be connected to a connecting pad portion of an uppermost wiring line of the low dielectric film wiring line laminated structure portion;
forming a bump electrode for external connection on the connection pad portion for the electrode;
forming a sealing film which covers a part of an upper surface of the insulating film surrounding the bump electrode for external connection, the side surfaces of the low dielectric film wiring line laminated structure portion, and the side surfaces of the insulating film; and
cutting the sealing film and the semiconductor wafer along the dicing streets, thereby obtaining a plurality of semiconductor devices.

21. The method according to claim 20, wherein the forming a sealing film includes filling the sealing film into the groove.

22. The method according to claim 20, further comprising forming a metallic underlayer to form the connection pad portion for the electrode and the bump electrode for external connection on the upper surface and the side surfaces of the insulating film and the side surfaces of the low dielectric film wiring line laminated structure portion, after removing the parts of the insulating film and the low dielectric film wiring line laminated structure portion in the regions above dicing streets and the regions on opposite sides of the dicing streets.

23. The method according to claim 22, further comprising forming an upper layer wiring line having the connection pad portion for the electrode on the metallic underlayer.

24. The method according to claim 23, further comprising forming the bump electrode for external connection on the upper layer wiring line.

25. The method according to claim 24, further comprising etching the metallic underlayer using the upper layer wiring line as a mask, after forming the bump electrode for external connection.

26. The method according to claim 20, wherein the low dielectric film includes one of a polysiloxane-based material having an Si—O bond and an Si—H bond, a polysiloxane-based material having an Si—O bond and an Si—CH₃ bond, a carbon-doped silicon oxide and an organic polymer-based low-k material, or a porous type of one of a fluorine-doped silicon oxide, boron-doped silicon oxide and silicon oxide.

27. A method of manufacturing a semiconductor device, comprising:
preparing a semiconductor wafer, on one surface of which an integrated circuit is formed, which includes a low dielectric film wiring line laminated structure portion constituted by low dielectric films and wiring lines, the low dielectric films having a relative dielectric constant of 3.0 or lower and a glass transition temperature of 400° C. or higher, and which includes a passivation film formed on the low dielectric film wiring line laminated structure portion;
removing parts of the passivation film and the low dielectric film wiring line laminated structure portion in regions above dicing streets and regions on opposite sides of the dicing streets by applying laser beams, and forming a groove exposing side surfaces of the low dielectric film wiring line laminated structure portion and the side surfaces of the passivation film;
forming an insulating film, which is formed of an organic resin and covers an upper surface of the passivation film and parts of the side surfaces of the passivation film and side surfaces of the low dielectric film wiring line laminated structure portion that are exposed through the groove;
forming a connection pad portion for an electrode on the insulating film to be connected to a connecting pad portion of an uppermost wiring line of the low dielectric film wiring line laminated structure portion;
forming a bump electrode for external connection on the connection pad portion for the electrode;
forming a sealing film which covers at least a part of an upper surface of the insulating film surrounding the bump electrode for external connection; and
cutting the sealing film and the semiconductor wafer along the dicing streets, thereby obtaining a plurality of semiconductor devices.

28. The method according to claim 27, wherein the forming a sealing film includes filling the insulating film into the groove, removing a central part of the insulating film filled into the groove, and filling the sealing film into the removed part of the insulating film.

29. The method according to claim 28, wherein the forming a sealing film includes covering side surfaces of the insulating film by the sealing film.

30. The method according to claim 27, wherein the removing parts of the passivation film and the low dielectric film wiring line laminated structure portion in regions above dicing streets and regions on opposite sides of the dicing streets includes applying laser beams to the passivation film and the low dielectric film wiring line laminated structure portion.

31. The method according to claim 27, wherein the low dielectric film includes one of a polysiloxane-based material having an Si—O bond and an Si—H bond, a polysiloxane-based material having an Si—O bond and an Si—CH₃ bond, a carbon-doped silicon oxide and an organic polymer-based low-k material, or a porous type of one of a fluorine-doped silicon oxide, boron-doped silicon oxide and silicon oxide.

32. A method of manufacturing a semiconductor device, comprising:
preparing a semiconductor wafer, on one surface of which a plurality of integrated circuits are formed, which includes a low dielectric film wiring line laminated structure portion constituted by low dielectric films and wiring lines, each of the low dielectric films having a relative dielectric constant of 3.0 or lower and a glass transition temperature of 400° C. or higher, and which includes an insulating film formed by patterning on the low dielectric film wiring line laminated structure portion and made of an organic resin;
removing parts of the low dielectric film wiring line laminated structure portion in regions above dicing streets and regions on opposite sides of the dicing streets by applying laser beams, and forming a groove exposing side surfaces of the low dielectric film wiring line laminated structure portion;
forming a plurality of connection pad portions for an electrode on the insulating film to be respectively connected to a plurality of connecting pad portions of a plurality of uppermost wiring lines of the low dielectric film wiring line laminated structure;
forming a bump electrode for external connection on the connection pad portion for the electrode;
forming a sealing film which covers a part of an upper surface of the insulating film surrounding the bump electrodes for external connection, the side surfaces of the low dielectric film wiring line laminated structure portion, and the side surfaces of the insulating film; and
cutting the sealing film and the semiconductor wafer along the dicing streets, thereby obtaining a plurality of semiconductor devices.

33. The method according to claim 32, wherein the preparing a semiconductor wafer includes forming a passivation film by patterning between the low dielectric film wiring line laminated structure portion and the insulating film.
